(19) United States
(12) Patent Application Publication
(10) Pub. No.: US 2011/0203663 A1
(43) Pub. Date: Aug. 25, 2011

(54) PHOTONIC CRYSTAL ENHANCED LIGHT TRAPPING SOLAR CELL

(76) Inventors: Dennis Prather, Newark, DE (US); Shouyuan Shi, Newark, DE (US); James Mutitu, Elkton, MD (US); Allen Barnett, Landenberg, PA (US)

(21) Appl. No.: 13/017,211

(22) Filed: Jan. 31, 2011

Related U.S. Application Data
(60) Provisional application No. 61/306,605, filed on Feb. 22, 2010.

(51) Int. Cl. H01L 31/0232

(52) U.S. Cl. 136/259

(57) ABSTRACT

This invention relates to a high efficiency solar cell comprising: (a) a top surface of an anti-reflective coating layer; (b) an engineered photonic crystal material layer, (c) an active photovoltaic layer; (d) a photonic crystals with an integrated diffraction grating; (e) a metallic diffraction grating reflective layer, and (f) a metallic back reflector;
whereby normally incident light striking the surface of the solar cell passes through the anti-reflective coating and the engineered photonic crystal material layer and is absorbed by active photovoltaic layer thereby generating electrical energy and obliquely incident light is reflected and diffracted by the engineered photonic crystal material layer, the one dimensional photonic crystal layer, the metallic grating reflective layer and the metallic back reflector to the active photovoltaic layer thereby generating electrical energy.

### CROSS REFERENCE TO RELATED APPLICATION

This application claims the benefit of provisional application 61/306,605 filed Feb. 22, 2010 which is incorporated herein in its entirety.

This invention was in part funded by the U.S. Government Defense Advanced Research Projects Agency under Agreement No.: HR0011-0709-0005. The Government has certain rights in the invention.

### FIELD OF THE INVENTION

This invention relates to a high efficiency thin film solar cell that has an enhanced light trapping design and the solar cell is suitable for use in both mobile and stationary applications.

### BACKGROUND OF THE INVENTION

The development of solar cells has been in progress for over fifty years. One-junction silicon solar cells have received much attention over that period and are used in terrestrial photovoltaic applications. However, a one-junction silicon solar cell captures less than half of the theoretical potential for solar energy conversion with the best laboratory silicon solar cells currently providing only about 24.7% efficiency. With such a low efficiency, large numbers of solar cells are required to generate electricity required for an application and this limits the usefulness of such cells to low electrical power applications or permanent applications wherein a large number of solar cells are used to supply sufficient electricity. It would be very desirable to have a high performance photovoltaic system for both economic and technical reasons. Many applications do not have the area required, for example, on the rooftops of domestic buildings or public or business buildings, to provide the needed power using current solar cells.

Different types of multi-device solar cell architectures have been proposed to improve solar cell efficiency. One is a lateral architecture. An optical dispersion element is used to split the solar spectrum into its wavelength components. Separate solar cells are placed under each wavelength band and the cells are chosen so that they provide good efficiency for light of that wavelength band. Another architecture is a vertical structure in which individual solar cells with different energy gaps are arranged in a stack. These are commonly referred to as cascade, tandem or multiple junction cells. The solar light is passed through the stack and hence, absorbed by the various layers of the solar cells.

A variety of solar cells have been developed to improve efficiency. For example, Yi et al. U.S. Pat. No. 7,482,532 issued Jan. 27, 2009 utilizes a solar cell having photonic crystal coupled to the photoactive region wherein the photonic crystal comprises a distributed Bragg reflector for trapping light. WO 2006/119305 utilizes a photovoltaic solar cell that achieves greater than 50% efficiency and can be manufactured at low cost on a large scale and has an integrated optical and solar cell design that allows for a broad choice of materials thereby enabling high efficiency with lower costs.

There is a need for a thin film high efficiency solar cell having improved overall optical efficiency and an architecture that enables entrapment of light that enables this improved efficiency.

### SUMMARY OF THE INVENTION

This invention is directed to a high efficiency solar cell of a multi-layered structure for the conversion of light striking the surface of the solar cell to electrical energy comprising:

(a) a top surface of an anti-reflective coating layer comprising

(1) a silicon oxide layer,

(2) a silicon nitride layer; and

(3) a thin silicon oxide layer;

(b) an engineered photonic crystal material layer comprising a photonic crystal layer engineered to allow normally incident light within a pass band of the material to pass through and obliquely incident light falling within the stop band range of frequencies of the material do not pass through the material; wherein the photonic crystal layer is comprised of a one, two or three dimensional photonic crystal;

(c) an active photovoltaic layer having an active photovoltaic region;

(d) a photonic crystal layer with an integrated diffraction grating structure;

(e) a metallic grating reflective layer; and

(f) a metallic back reflector;

whereby normally incident light striking the surface of the solar cell passes through the anti-reflective coating and the engineered photonic crystal material layer and is absorbed by the active region of the photovoltaic layer thereby generating electrical energy and obliquely incident light is reflected by the engineered photonic crystal material layer and whereby the photonic crystal layer, the metallic grating reflective layer and the metallic back reflector, reflect light back to the active photovoltaic region thereby generating electrical energy.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIG. 1. Design of a solar cell structure that it incorporates an EPhCM and a binary grating for optical path length enhancement.

FIG. 2. Design of solar cell structure that incorporates an EPhCM and blazed diffraction grating.

FIG. 3. Illustrates the operation of the EPhCM in which normally incident light waves propagate through the EPhCM structure while obliquely incident light waves are reflected.

FIG. 4. Illustrates a multiple device stack architecture of a solar cell structure showing the benefits of the selective light filtering 1D-PhC and layers of an angular dependent EPhCM and solar cells C1 and C2 consist of different materials.

FIG. 5. Design of a solar cell structure that incorporates an EPhCM and a double diffraction grating.

FIG. 6. illustrates parameters of the EPhCM, the lattice constant, a, and the width of the a-Si squares, w, and also shows an incident TM polarized light wave at the top of the structure.

FIG. 7. Illustrates the equi-frequency contours for the EPhCM structure with the normalized frequencies of the EFC's being 0.2 c/a (Blue EFC) and 0.21 c/a (red EEC) and the shaded area shows the variation in the admissible angles for the incident wave vector.

FIG. 8. Illustrates a normally incident plane windowed wave of light, that propagates through the EPhCM structure and reaches detectors labeled DN1, DN2 and DN3. The amplitude of the wave at the three detectors (shown as crosses) of the transmitted normally incident wave of light is shown.

FIG. 9. Illustrates the same EPhCM structure with light incident at 45 degrees from the solar cell active region where the wave is reflected by the EPhCM structure and almost nothing propagates to the detectors DO1, DO2 and DO3. The amplitude of the wave at the three detectors (shown as crosses) of the transmitted normally incident wave of light is shown.

FIG. 10. Illustrates a design schematic of a solar cell fitted with an an EPhCM structure, i.e. the SCEPhCM.

FIG. 11. Illustrates the short circuit current characteristics (Jsc) in relation to wave length (nm) of solar cell having the EPhCM structure, (green plot line), compared to a silicon solar cell without the EPhCM structure (blue plot line) compared to the maximum available short circuit current (red plot line).

FIG. 12. Illustrates the enhancement factor in relation to wavelength of a solar cell having the EPhCM structure to the same cell without the EPhCM structure.

FIG. 13. Illustrates the tolerance analysis of the squared rod width, w, of the EPCM structure in terms of the Jsc characteristics at the silicon band-edge (867-1100 nm).

### DETAILED DESCRIPTION OF THE PREFERRED EMBODIMENTS

Definitions of terms as used herein:

“AR Coating” means an anti reflective coating.

“c-Si” means crystalline silicon.

“a-Si” means amorphous silicon.

“EPhCM” means engineered photonic crystal material.

“PhCs” means photonic crystals.

“ID PhC” means one dimensional photonic crystal.

“2D-PhC” means two dimensional photonic crystal.

“3D-PhC” means three dimensional photonic crystal.

“Solar Cell” is used to describe the entire device.

“TFSC” means thin film solar cell.

“TIR” means total internal reflectance of a solar cell.

“Absorbed” as used herein, means that a photon absorbed by the cell results in the creation of an electron-hole pair and the energy of the photons is converted into electrical energy.

All percentages expressed herein are by weight of the total weight of the composition unless expressed otherwise.

Ranges are used herein in shorthand, to avoid having to list and describe each and every value within the range. Any appropriate value within the range can be selected, where appropriate, as the upper value, lower value, or the terminus of the range.

As used herein, the singular form of a word includes the plural, and vice versa, unless the context clearly dictates otherwise. Thus, the references “a”, “an”, and “the” are generally inclusive of the plurals of the respective terms. For example, reference to “a method” includes a plurality of such “methods”. Likewise the terms “include”, “including” and “or” should all be construed to be inclusive, unless such a construction is clearly prohibited from the context. Similarly, the term “examples,” particularly when followed by a listing of terms, is merely exemplary and illustrative and should not be deemed to be exclusive or comprehensive.

The term “comprising” is intended to include embodiments encompassed by the terms “consisting essentially of” and “consisting of”. Similarly, the term “consisting essentially of” is intended to include embodiments encompassed by the term “consisting of”.

The methods and compositions and other advances disclosed herein are not limited to particular equipment or processes described herein because, as the skilled artisan will appreciate, they may vary. Further, the terminology used herein is for the purpose of describing particular embodiments only, and is not intended to, and does not, limit the scope of that which is disclosed or claimed.

Unless defined otherwise, all technical and scientific terms, terms of art, and acronyms used herein have the meanings commonly understood by one of ordinary skill in the art in the field(s) of the invention, or in the field(s) where the term is used. Although any compositions, methods, articles of manufacture, or other means or materials similar or equivalent to those described herein can be used in the practice of the present invention, the preferred compositions, methods, articles of manufacture, or other means or materials are described herein.

All patents, patent applications, publications, technical and/or scholarly articles, and other references cited or referred to herein are in their entirety incorporated herein by reference to the extent allowed by law. The discussion of those references is intended to merely summarize the assertions made therein. No admission is made that any such patents, patent applications, publications or references, or any portion thereof, are relevant, material, or prior art. The right to challenge the accuracy and pertinence of any assertion of such patents, patent applications, publications, and other references as relevant, material, or prior art is specifically reserved.

The instant invention provides for increased light trapping capacity of the solar cell that in turn improves the current output of the cell and thereby improves the overall efficiency of the cell. The absorption of light in a solar cell is enhanced by reducing the front surface light reflection and increasing the optical path length of light within the solar cell. This is accomplished by using an antireflective surface coating on the solar cell along with multiple layers of light reflecting materials that transmit light or reflect light having photons of energy that are absorbed by the active region of the photovoltaic layer that generates electrical energy.

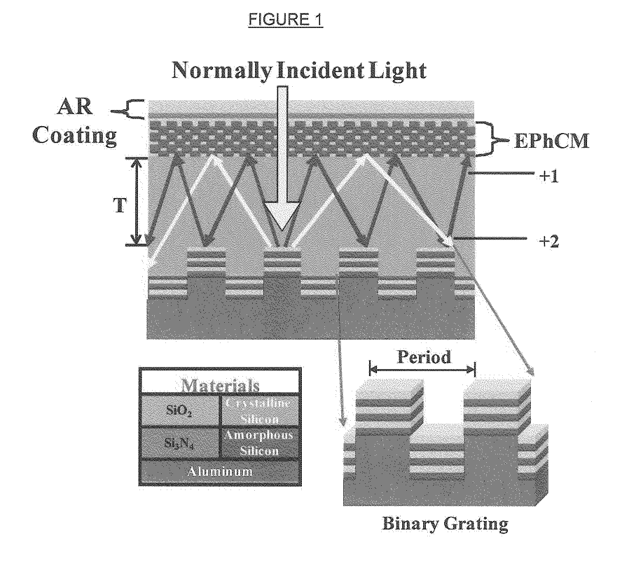

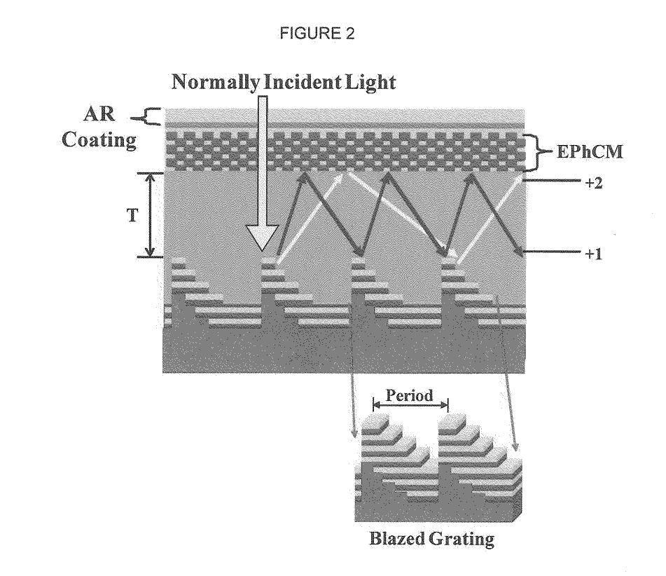

FIG. 1 shows the design of a solar cell structure that incorporates a binary grating for optical path length enhancement and FIG. 2 shows the design of a solar cell structure that incorporates a blazed grating for optical path length enhancement. Included in both FIGS. 1 and 2 is a representation of the different optical path lengths for the first (+1) and second (+2) diffracted orders. The letter T in both FIGS. 1 and 2 denotes the thickness of the active photovoltaic layer. This thickness is arbitrary because the design of the solar cell can be extended to both thin and thick film solar cells.

FIG. 1 shows a solar cell having an AR (anti-reflective) coating layer, typically about 50-300 nm in thickness, comprising a silicon oxide (SiO2) layer, a silicon nitride (Si3N4) layer and a silicon oxide (SiO2) layer that typically reduces reflectance from about 31% to about 4.5%. The layer below the anti-reflective layer is an EPhCM layer comprising a photonic crystal layer of either 1, 2 or 3 dimensional photonic crystals that allows normally incident light to pass through to the photovoltaic layer for the absorption of light energy (photons) which are converted to electrical energy and oblique light waves are reflected. Oblique incident light is reflected back to the AR (anti-reflective) coating layer and out into free space. Below the EPhCM layer, is the photovoltaic layer (T) that converts light energy into electrical energy. Arrows depict the different optical path lengths for the first (+1) and second (+2) diffracted orders of light. The thickness of the active photovoltaic layer (T) can vary from a thin layer to a relatively thick layer T.

A binary grating is positioned below the active photovoltaic layer (T) that diffracts and then reflects light back into the active photovoltaic layer. This grating is formed of intermittent layers of materials with a high refractive index contrast, e.g., SiO₂ and amorphous silicon in the case of a silicon active layer. The thickness of the grating depends on the specific wavelength band of interest, i.e., for diffraction. The wavelength band, in turn, depends on the type of material used in the active photovoltaic layer and this can be any material used in solar electric science.

Below the binary grating is a 1D-PhC layer (one dimensional photonic crystal layer) of alternating silicon and SiO₂ layers which reflects light back into the solar cell.

For single junction applications, the solar cell structure has a bottom layer of a metallic material, e.g., aluminum, that also reflects the light that has passed through the 1D-PhC layers back into the active region of the photovoltaic layer.

FIG. 2 shows a design of solar cell structure that is similar in structure to the solar cell of FIG. 1. The cell contains an AR (anti-reflective) coating layer as described above, an EPhCM layer, as described above, an active photovoltaic layer having an active region for the absorption of light energy (photons) which are converted to electrical energy. As in FIG. 1, oblique incident light is reflected back to the AR (anti-reflective) coating layer. Arrows depict the different optical path lengths for the first (+1) and second (+2) diffracted orders of light. A blazed grating is positioned below the active photovoltaic layer that diffracts and reflects light back into the active photovoltaic layer. This grating is formed of intermittent layers of materials with a high refractive index contrast, e.g., SiO₂ and amorphous silicon in the case of a silicon active layer.

Binary rectangular gratings are generally preferred because they are less difficult to fabricate; however, they are not the most effective when it comes to light trapping in thin solar cells. More effective, asymmetric blazed gratings and multiple gratings can be used with the same solar cell structure. When using blazed gratings, they can be designed in such a manner that zero and negative (left moving) orders are suppressed and hence, only positive (right moving) orders remain thereby increasing the light trapping capability.

For single junction applications or stand alone applications, the solar cell structure has a bottom layer of a metallic material, e.g., aluminum, that also reflects the light that has passed through the 1D-PhC layers back into the active photovoltaic region of the cell.

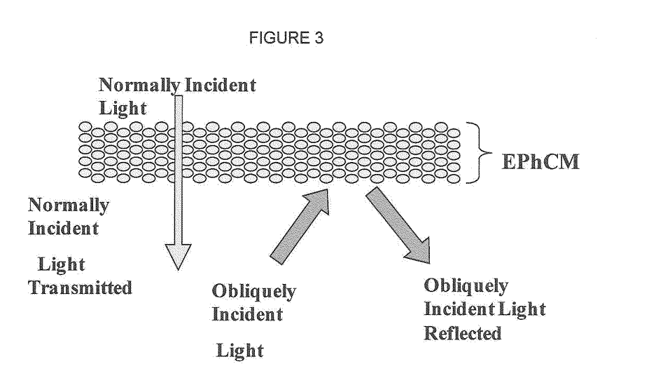

FIG. 3 illustrates the operation of EPhCM structure. Normally incident light waves propagate through the EPhCM structure while obliquely incident light waves are reflected. The EPhCM is a specially engineered PhC structure designed in such a way that normally incident light (illustrated by the vertical arrow) passes through. The incident light falls within the pass band (range of frequencies allowed to propagate through the EPhCM structure) while obliquely incident light falls within the stop band (range of frequencies that do not propagate through the EPhCM structure) and are reflected back to the AR coating and then reflected back into the solar cell. The EPhCM layer reduces optical losses that normally occur.

The EPhCM layer is designed only for normally incident light waves and any diffracted waves which are obliquely incident on the EPhCM will be reflected due to the stop band of the structure. One, two or three dimensional photonic crystals can be used to form the EPhCM layer depending on the level of light entrapment desired for the particular solar cell structure. The TIR (total internal reflection) conditions of the solar cell are due to the reflection of the obliquely incident light waves by the EPhCM, rather than primarily on the effects of the refraction of light.

To fully understand the physical phenomena of the EPhCM, a description of a PhC is provided. A PhC is a periodic arrangement of dielectric or metallic materials with a lattice constant comparable to the wavelength of an electromagnetic wave (light wave). A simple example, is a 1D-PhC, having alternating layers of material having different refractive indices that are stacked to form a structure that is periodic along one direction. Depending on the effects desired, the EPhCM layer can be formed with 2D-PhCs and or 3D-PhCs. The interaction of an electromagnetic wave with the periodic dielectric structure results in an interference pattern that allows for some light to propagate or be reflected from the different layers of the structure. This phenomenon is described in a band structure, which determines the range of frequencies that are permitted to propagate through and those that are not. The parameters that determine the band structure are the refractive index contrast and thickness of the corresponding layers.

A PhC can be designed so that normally incident light falls within the pass band of the PhC (range of frequencies allowed to propagate through the structure) and obliquely incident light falls within the stop band (range of frequencies that do not propagate through structure). This is the EPhCM and its function is illustrated in FIG. 3. The EPhCM structure prevents optical losses that occur due to out-coupling of light from the solar cell structures. This comes about because, in solar cell structures with symmetric gratings, such as rectangular binary gratings, diffracted orders propagate to the left and right of the grating with the same angle (for the same positive and negative orders) and same magnitude. With the EPhCM designed for only normally incident light waves, any diffracted waves which are obliquely incident on the EPhCM will be reflected due to the stop band of the structure. The TIR conditions are a consequence of reflection, or non-admittance, of obliquely incident light waves, rather than primarily of the effects of the refraction of light. This effect also increases the design tolerance of the diffraction grating, since the critical angle of the active photovoltaic material, for example, c-Si, is no longer a limiting factor in the design of gratings used in solar cells.

The EPhCM structure can be formed using micro and nanotechnology fabrications processes. These include, but are not limited to, semiconductor fabrication processes, such as, plasma enhanced chemical vapor deposition, electron beam lithography and inductively coupled plasma etching.

To improve the optical efficiency of the solar cell, the EPhCM layer is used in conjunction with a binary or a blazed grating as shown in FIGS. 1 and 2, respectively. The gratings are designed to minimize zero order diffraction. Positive first and second order diffractive waves propagate through the structure and are totally reflected by the EPhCM due to its angular dependent stop-band.

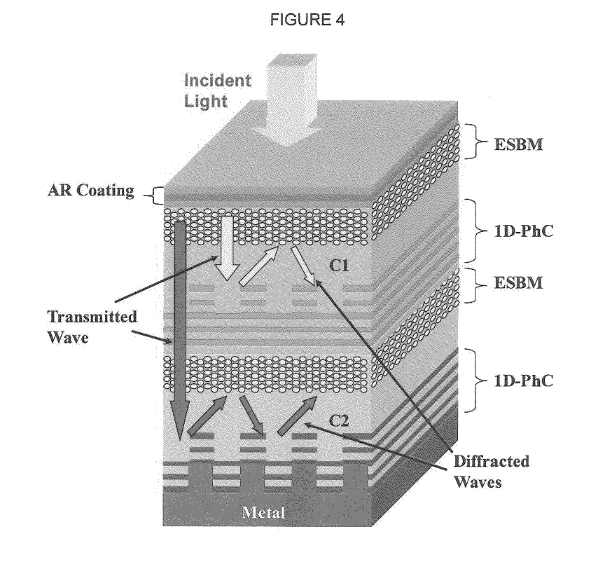

FIG. 4 illustrates a multiple device stack solar cell structure showing the benefits of the selective light filtering 1D-PhC and angular dependent EPhCM. The solar cell has an AR coating layer comprising a silicon oxide (SiO₂) layer, a silicon nitride (Si₃N₄) layer and a silicon oxide (SiO₂) layer. Incident light enters the cell wherein a portion of the transmitted light wave is passed directly to the active layer, C1, for absorption of light energy, which is converted to electrical energy, and then the remainder of the wave is absorbed by active layer, C2, and also converted into electrical energy. The layer below the AR layer is an EPhCM layer, as described above, that allows incident light to pass through to the active layer C1 of the active photovoltaic material below the EPhCM layer for the absorption of light energy and conversion into electrical energy and any oblique light waves are reflected. Oblique incident light is reflected back to the AR (anti-reflective) coating layer and into free space. Arrows depict the different optical path lengths for the first and second diffracted orders of light.

A binary grating is positioned below the active photovoltaic layer, C1, that reflects light back into the active photovoltaic layer, C1. This grating is formed of intermittent layers of materials with a high refractive index contrast, e.g., SiO₂ and amorphous silicon; in the case of a silicon active layer.

Below the binary grating is a 1D-PhC layer of alternating silicon and SiO₂ layers which reflects light back into the solar cell. Below the binary grating is a second EPhCM layer which functions like the first EPhCM layer allowing normally incident light to pass through and reflecting obliquely incident light. Incident light passing through the EPhCM layer is absorbed by the C2 layer, and is converted into electrical energy. A binary grating is positioned below the C2 layer that reflects light back into the C2 layer. Below the binary grating is a 1D PhC layer that reflects light back into the solar cell.

In solar cells having more than one active photovoltaic layer, a combination of different layers can be designed to accomplish a high level of light entrapment and hence conversion to electrical energy to form a high efficiency solar cell. Examples of materials that can be used to form these different active photovoltaic layers are CdTe, GaAs, CIGS, SiGe, c-Si, InGaAs, InGaAsP, InP, GaInPAsSb, GaSb, GaP, and a-Si.

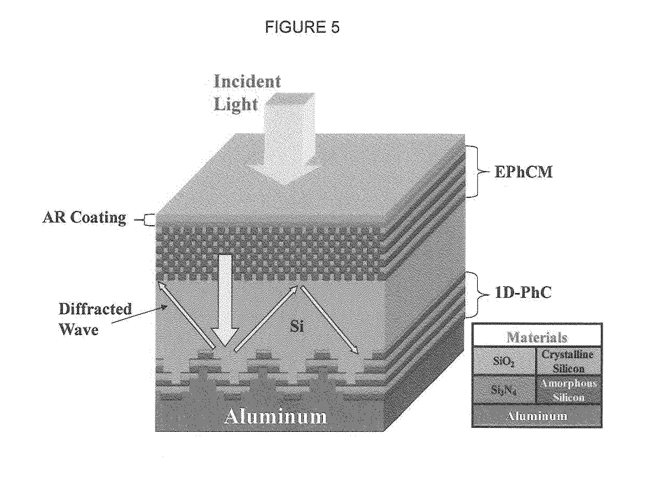

FIG. 5 shows a design of a solar cell structure that incorporates the EPhCM layer and a double diffraction grating wherein the diffracted light waves are trapped within the active silicon region because of the stop bands in the EPhCM layer.

A variety of geometries for gratings can be used in solar cells. FIG. 5 illustrates a triangular symmetric grating. FIG. 1 shows a symmetrical rectangular binary grating wherein the shape is rectangular and symmetric and hence, light waves impinging on the grating will be diffracted in both the left and right equally. FIG. 2 illustrates an asymmetrical blazed grating that diffracts the light in one direction, to the right only as shown.

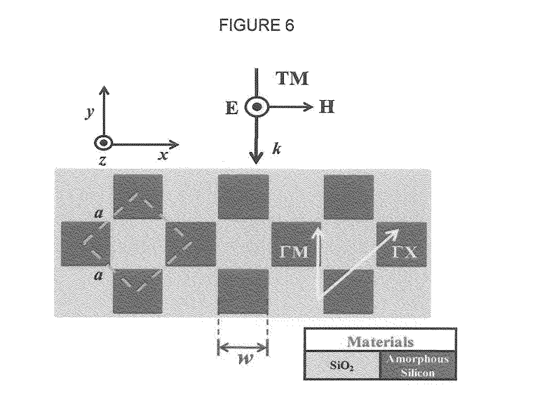

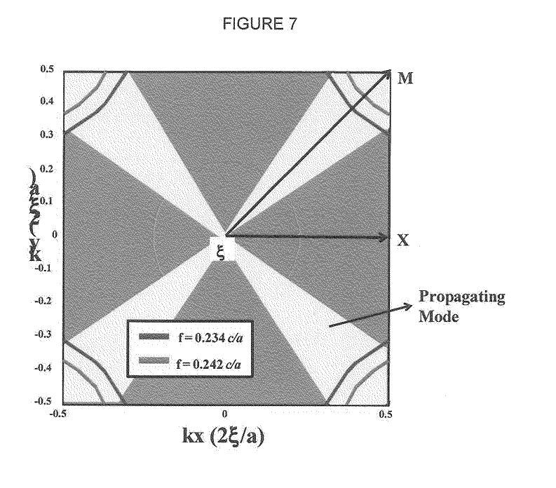

FIG. 6 shows an example of the EPhCM structure used in the solar cells of this invention (in this case the EPhCM is represented by a 2D-PhC). The lattice constant, a, and the width of the a-Si squares, w, are shown and also shown is incident TM polarized light wave at the top of the structure. The EPhCM structure illustrated is a PhC (2D-PhC) in which the dispersion properties are engineered in such a way as to allow the propagation of light incident at certain angles while disallowing the passage of obliquely incident light. In designing the EPhCM, a square lattice of square shaped dielectric columns made of amorphous silicon (a-Si), with w/a=0.7 where w is the width of the square “rods” and a is the lattice constant of the EPhCM, embedded in a slab of SiO2, as shown in FIG. 6 was used. The lattice constant is equal to the product of the design wavelength and the normalized frequency; thus for a design wavelength of 867 nm and a normalized frequency of 0.242 c/a, a=210 nm. The width of the square rods, w, is therefore 0.45a=94.5 nm. The period of the EPhCM is 297 nm; this is the diagonal of the green-dashed square in FIG. 6. Square shaped columns were used so as to enable accurate further analysis using the S-Matrix method, in which square and rectangular geometries are easily described and analyzed. The S-Matrix method, when used with multiple stacked layers, regardless of the thickness of each layer, is more efficient than volumetric numerical electromagnetic techniques, such as the finite element method or FDTD. The unit cell in this case is a square lattice of square-shaped columns which are rotated by an angle of 45 degrees; thus the EFCs (equi-frequency contours) appearing at the edges, in FIG. 7, correspond to normally incident light. The entire structure is then rotated again by 45 degrees to ensure that the propagating modes occur at normal incidence. The resultant structure assumes a “chess-board” pattern as shown in FIG. 6.

The rationale behind the operation can be understood by considering the EPhCM as consisting of an array of periodic squares of high-index materials (a-Si in this case) embedded in a slab of a lower-index material (SiO₂ in this case). The relationship between the frequency, v, and its associated wave vector k, is described in a dispersion diagram. The dispersion diagram is achieved by solving Maxwell's equations, as an eigen value problem, through the use of computational electromagnetic simulation methods, such as, the plane wave method and FDTD. The solutions obtained represent a dispersion surface; this is achieved by computing all the eigen frequencies for wave vectors at all k points within the irreducible Brillouin zone and then applying the appropriate symmetry operations. The shapes of the dispersion surfaces are dependent on the fill-factor, lattice type, pitch or index of refraction. By taking cross sections of the dispersion surfaces at constant frequencies equifrequency contours (EFCs) are obtained; some EFCs for TM polarization of the EPhCM structure are shown in FIG. 7. Kx and Ky are the wave vector components. The shaded region (in FIG. 7) shows the range of angles in which an incident wave will be allowed to propagate through the EPhCM, this is mainly in the T-M direction. The direction of energy flowing in a propagating light wave is described by the group velocity which is given in the following equation:

v_{g}=∇ₖω(k)

The group velocity, v_{g}, is a vector pointing in the direction of steepest ascent of the dispersion surface and is thus perpendicular to the EFC.

In 2D-PhCs that can be used to for the EPhCM, the electric fields can by divided into two polarizations by symmetry, namely transverse electric (TE) and transverse magnetic (TM). In TE mode, the electric field is in the PhC plane (in the x-y plane) and the magnetic field is perpendicular to the plane (z plane). In TM mode, the magnetic field is in the x-y plane of the PhC while the electric field is perpendicular (in the z plane) to the plane (x-y). The band structures for the two polarizations, TE and TM are completely different. In a structure in which high-index “rods” are embedded in a lower-index medium, there needs to exist thin vein lines along which the electric field lines can run (i.e., of the lower index dielectric material). Thus, the EPhCM structure is best suited for TM polarized waves. Since Maxwell's equations are scale invariant, the solution obtained, with the EFC, can be applied to any wavelength by choosing the appropriate value for the lattice constant.

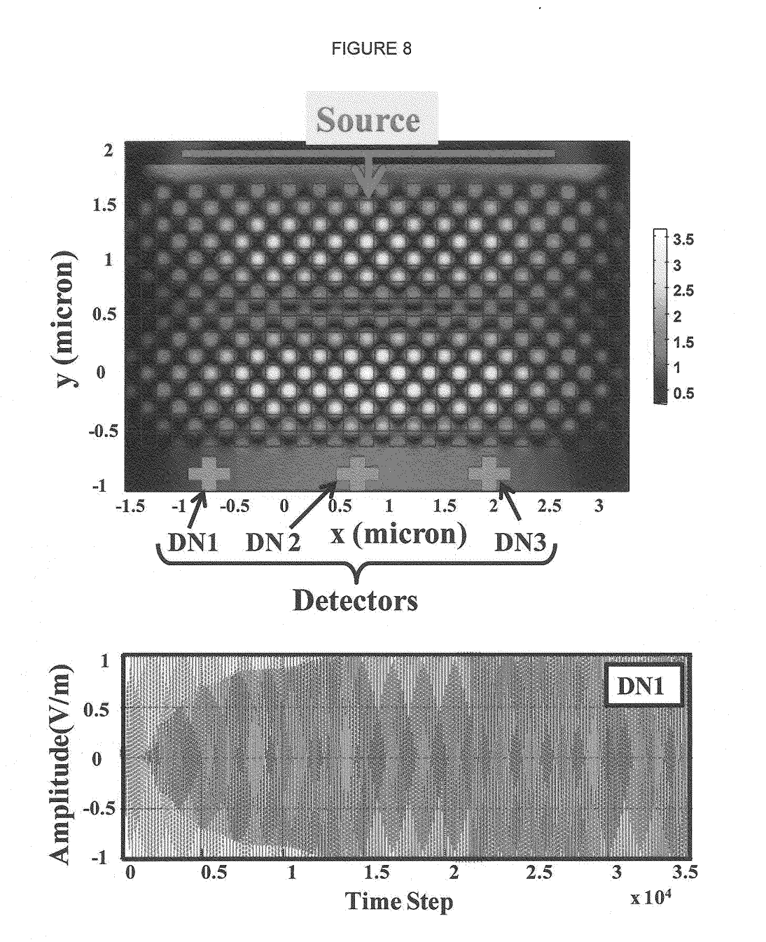

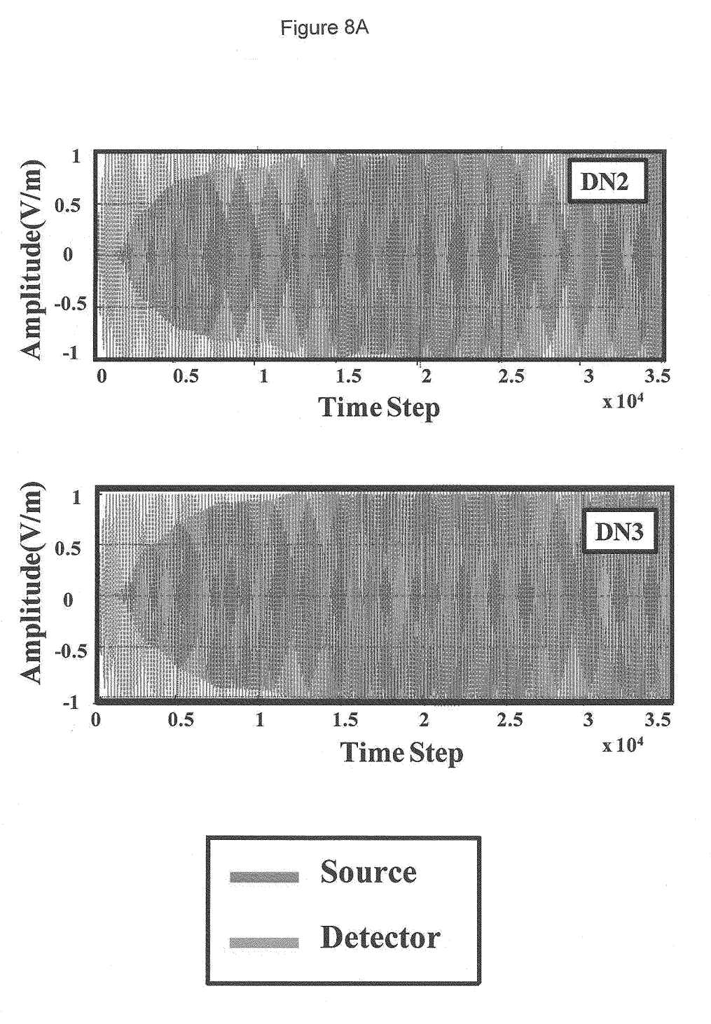

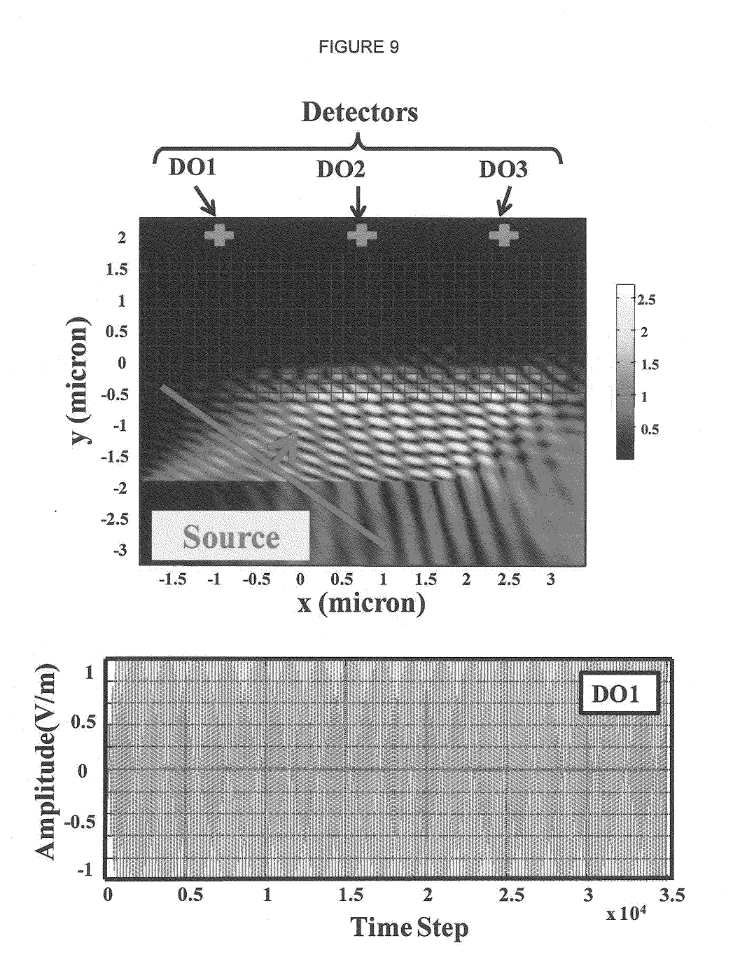

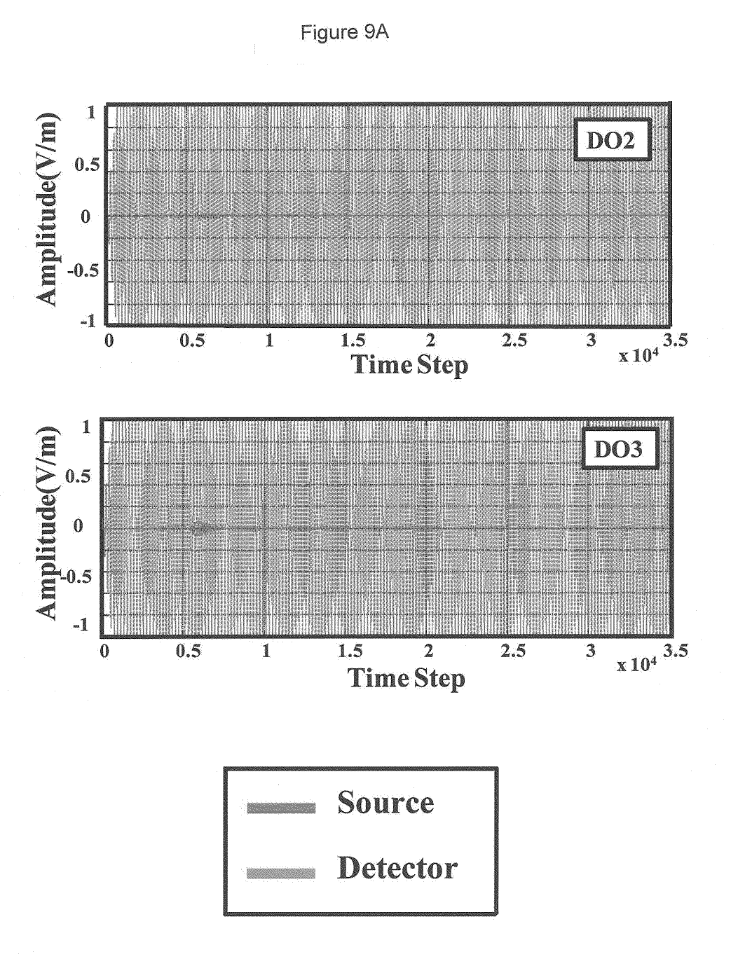

The EPhCM shows strongest angular selective characteristics for TM mode polarization, and hence the angular selective behavior of the structure for this polarization is analyzed. The FDTD method is used to simulate the wave propagation (at 867 nm wavelength) through the EPhCM structure, and the results are shown in FIG. 8. FIG. 8 shows a normally incident plane windowed wave, that propagates through the EPhCM structure and reaches the detectors labeled DN1 DN2 and DN3, FIG. 9, shows the same EPhC structure, with light incident at 45 degrees, from the solar cell active region; the wave is reflected by the EPhCM structure and almost nothing propagates to the detectors labeled DO1, DO2 and DO3. FIG. 8 shows the amplitude at various time steps of the wave at these detectors (green crosses) transmitted from the normally incident wave of FIG. 8, Similarly, FIG. 9 shows the amplitude at various time steps of the wave at the three detectors transmitted from obliquely incident wave.

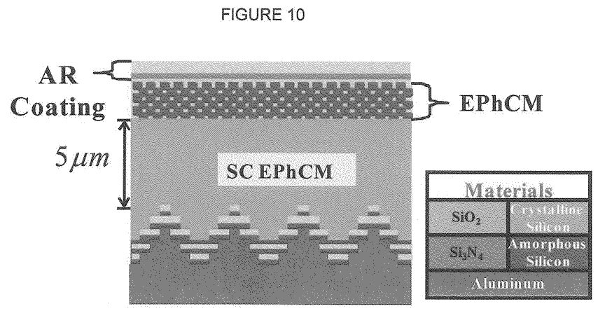

FIG. 10 shows a solar cell having a hybrid dielectric metallic structure (HDM3) having a triangular grating and the EPHCM structure.

The solar cell has a double layer AR coating that consists of a top silicon dioxide (SiO₂) layer and a layer of silicon nitride (Si₃N₄). The thickness of the c-Si active layer is 5 μm. The grating consists of the 1D-PhC structure overlapping an aluminum structure. The 1D-PhC grating consists of four alternating layers above the aluminum grating and four alternating layers inter-digitated with the aluminum grating as shown in FIG. 10. The four alternating layers of the above the aluminum grating comprise a 1D-PhC structure of alternating a-Si and SiO₂ layers that are cut through to make the triangular gratings structures. The thickness of each period of the metallic triangular grating corresponds to the thicknesses of the a-Si and SiO₂ layers in the 1D-PhC. With four alternating layers that correspond to the metallic grating, the metal has eight periods. The periods of the four alternating 1-DPhC layers for the top grating are 90 nm, 270 nm, 450 nm and 630 nm. The eight periods of the aluminum layer grating are calculated by multiplying each factor in the list of 0.1, 0.2, . . . , 0.8 by 900 nm. At the very base of the design is a flat aluminum layer of 1 μm thickness is added. A summary for the optimal design parameters of such a solar cell are in the following Table 1 when the EPhCM layer is adjusted to a predetermined thickness.

TABLE 1

| Design Structure | Optimal Design Parameters | |
|---|---|---|
| AR coating top layer (Si0₂) | 99 | nm |
| AR coating second layer (Si₃N₄) | 49 | nm |
| Silicon active layer | 5 | μm |
| Triangular grating period (both 1D- | 900 | nm |
| PhC and aluminum) | | |
| 1D-PhC SiO₂ layer thickness | 170 | nm |
| 1D-PhC a-Si layer thickness | 79 | nm |
| Triangular grating thickness | 996 | nm |
| (both1D-PhC and aluminum) | | |
| Aluminum back relector thickness | 1 | μm |

In general, the optimal design parameters for the TFSC of this invention are as follows:

| | |
|---|---|
| AR coating top layer (SiO₂) | 99 nm (1 nm-10 microns) |
| AR coating second layer (Si₃N₄) | 49 nm (1 nm-10 microns) |
| AR passivation layer (SiO₂) | 8 nm (1 nm-10 microns) |
| EPhCM layer | Adjusted to a predetermined thickness |
| Silicon active layer | 5 μm (1 nm-1 cm) |
| Grating layer | 900 nm (1 nm-1 cm) |
| 1D PhC layer | 258 nm (1 μm-1 cm) |

The light trapping performance of a solar cell is related to the short circuit current (Jsc) of the cell through its absorption characteristics using the equation below:

$${J}_{SC} = \frac{q}{hc} {\int }_{λ} {λ}^{′} A ( {λ}^{′} ) Irrd ( {λ}^{′} ) d {λ}^{′}$$

where Jsc is the short circuit current density, q is the charge of an electron, h is Planck's constant, c is the speed of light, λ′ is the wavelength, A is the absorption of the active voltaic structure and Irrd is the solar radiance spectrum.

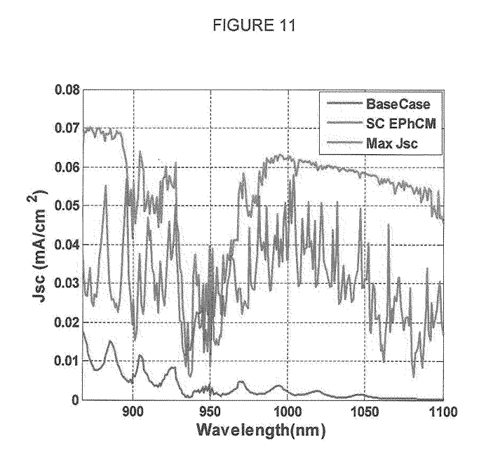

The Jsc performance of the EPhCM solar cell was compared to those of a base case solar cell (cell with no light-trapping) and to the maximum Jsc available. The comparison is shown in FIG. 11. The band-edge (wavelength 867-1100 nm) Jsc of the EPhCM structure is substantially more than the base case solar cell having no light-trapping capability. It should be noted that at about 1100 nm, the base case solar cell exhibits close to zero absorption and hence, the enhancement in Jsc characteristics of the EPhCM solar cell is very significant.

A second performance characteristic of the TFSC of this invention is the enhancement factor (EF) which is the ratio of the average band edge absorption of the of a solar cell with light trapping structures in comparison to a solar cell having no light trapping structures. EF is calculated according to the following equation:

$$EF ( λ ) = \frac{{\int }_{λ}^{λ = 1100} {A}_{E} ( {λ}^{′} ) Irrd ( {λ}^{′} ) d {λ}^{′}}{{\int }_{λ}^{λ = 1100} {A}_{s} ( {λ}^{′} ) Irrd ( {λ}^{′} ) d {λ}^{′}}$$

where the value A_{E} represents the absorption characteristics of an enhanced structure, i.e., with the AR coating at the top surface and light trapping structures at the bottom surface, A_{S} represents the absorption of a solar cell structure with no light trapping structures at the top or bottom surfaces. Irrd and λ′ are defined above.

The enhancement factor (EF) of different solar cell structures were compared. The EPhCM containing structure (the light-trapping enhanced structure) to those of the base-case structure with no light trapping and to an HDM3 structure without EPhCM. The addition of the EPhCM increases the absorption characteristics by a factor of 250 above that of a base structure with no EPhCM at about 1100 nm.

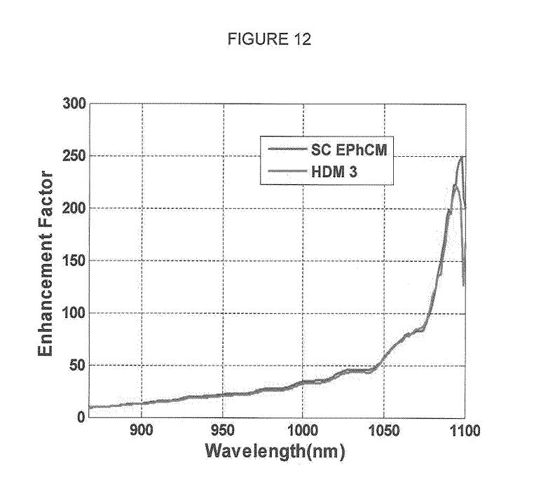

FIG. 12 shows the enhancement factor comparison of the solar cell structure which includes the EPhCM structure (blue plot), and the HDM 3 structure which does not include the EPhCM (green plot). The EPhCM structure enhances the absorption of light by a factor of almost 250 at the silicon band-edge.

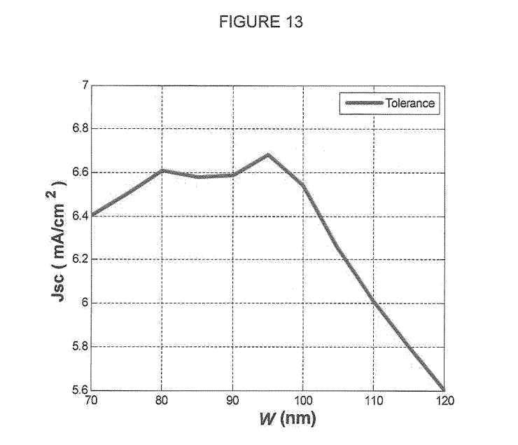

FIG. 13 illustrates the tolerance analysis of the squared rod width, w, of the EPCM structure in terms of the Jsc characteristics at the silicon band-edge (867-1100 nm).

The high enhancement factor of the EPhCM fitted solar cell is a clear indicator of the benefits obtained by using the EPhCM structure in a thin-film solar cell.

The scope of the invention is set forth in the claims.

What is claimed is:

1. A high efficiency solar cell of a multi-layered structure comprising:
(a) a top surface of an anti-reflective coating layer;
(b) an engineered photonic crystal material layer comprising a photonic crystal layer engineered to allow normally incident light within a pass band of the material to pass through and obliquely incident light falling within the stop band range of frequencies of the material do not pass through the material; wherein the photonic crystal layer comprises photonic crystals selected from the group consisting of one, two or three dimensional photonic crystals;
(c) an active photovoltaic layer having an active photovoltaic region,
(d) a photonic crystal layer with integrated diffraction grating structures;
(e) a metallic grating reflective layer; and
(f) a metallic back reflector:
whereby normal incident light striking the surface of the solar cell passes through the anti-reflective coating and the engineered photonic crystal material layer and is absorbed by the active region of the photovoltaic layer thereby generating electrical energy and obliquely incident light is reflected by the specially engineered stop band material; and
whereby the photonic crystal layer, the metallic grating reflective layer and the metallic back reflector reflect light back to the active region of the photovoltaic layer thereby generating electrical energy.

2. The high efficiency solar cell of claim 1, wherein the anti-reflective coating comprises (1) a silicon oxide layer, (2) a silicon nitride layer; and (3) a thin silicon oxide layer.

3. The high efficiency solar cell of claim 1, wherein the engineered photonic crystal material layer is comprised of one, two or three dimensional photonic crystal structures or metallic photonic crystal structures or combinations of dielectric and metallic photonic crystal structures.

4. The high efficiency solar cell of claim 1, wherein the metallic grating reflective layer comprises a binary diffraction grating, a blazed diffraction grating, a double diffraction grating or a triangular diffraction grating.

5. The high efficiency solar cell of claim 1, wherein the anti-reflective coating comprises (1) a silicon oxide layer, (2) a silicon nitride layer; and (3) a thin silicon oxide layer and wherein the engineered photonic crystal material layer is comprised of one, two or three dimensional photonic crystal structures or metallic photonic crystal structures or combinations of dielectric and metallic photonic crystal structures and wherein the metallic grating reflective layer comprises a binary diffraction grating, a blazed diffraction grating, a double diffraction grating or a triangular diffraction grating.

6. A high efficiency solar cell of a multi-layered structure comprising:
(a) a top surface of an anti-reflective coating layer;
(b) an engineered photonic crystal material layer comprising a photonic crystal layer engineered to allow normally incident light within a pass band of the material to pass through and obliquely incident light falling within the stop band range of frequencies of the material do not pass through the material; wherein the photonic crystal layer comprises photonic crystals selected from the group consisting of one, two or three dimensional photonic crystals;
(c) an active photovoltaic layer;
(d) a layer of one dimensional photonic crystals with an integrated diffraction grating;
(e) a second an engineered photonic crystal material layer comprising a photonic crystal layer engineered to allow normally incident light within a pass band of the material to pass through and obliquely incident light falling within the stop band range of frequencies of the material do not pass through the material; wherein the photonic crystal layer comprises photonic crystals selected from the group consisting of one, two or three dimensional photonic crystals;
(f) a second active photovoltaic layer having an active photovoltaic region different from the first active photovoltaic layer;
(g) a second layer of a one dimensional photonic crystal cells;
(h) a metallic grating reflective layer;
(i) a metallic back reflector;
whereby normally incident light striking the surface of the solar cell passes through the anti-reflective coating and the engineered photonic crystal material layer and is absorbed by the active photovoltaic layer thereby generating electrical energy and obliquely incident light is reflected by the engineered photonic crystal material layer and whereby, the one dimensional photonic crystal layer, the metallic grating reflective layer and metallic back diffracts and reflects light back to the active photovoltaic layer thereby generating electrical energy;
whereby any normally incident light passes through layers (a) through (d) then passes through the second layer of the engineered photonic crystal material layer (e) and is absorbed by the second active photovoltaic layer thereby generating electrical energy and obliquely incident light is reflected by the second layer of the engineered photonic crystal material layer, the one dimensional photonic crystal layer, the metallic grating reflective layer and metallic back reflector diffracts and reflects light back to the active region of the second photovoltaic layer thereby generating electrical energy.

7. The high efficiency solar cell of claim 6, wherein the anti-reflective coating comprises (1) a silicon oxide layer, (2) a silicon nitride layer; and (3) a thin silicon oxide layer.

8. The high efficiency solar cell of claim 6, wherein the layers of the engineered photonic crystal material layer comprise is comprised of one, two or three dimensional photonic crystal structures or metallic photonic crystal structures or combinations of dielectric and metallic photonic crystal structures.

9. The high efficiency solar cell of claim 6, wherein the metallic grating reflective layers each comprise a binary diffraction grating, a blazed diffraction grating, a double diffraction grating or a triangular diffraction grating.

10. The high efficiency solar cell of claim 6, wherein the anti-reflective coating comprises (1) a silicon oxide layer, (2) a silicon nitride layer; and (3) a thin silicon oxide layer and wherein the layers of the engineered photonic crystal material layer comprise is comprised of one, two or three dimensional photonic crystal structures or metallic photonic crystal structures or combinations of dielectric and metallic photonic crystal structures and wherein the metallic grating reflective layers each comprise a binary diffraction grating, a blazed diffraction grating, a double diffraction grating or a triangular diffraction grating.
